(19) United States
(12) Patent Application Publication
(10) Pub. No.: US 2026/0324043 A1
(43) Pub. Date: Oct. 15, 2026

(54) TRANSISTOR STRUCTURE WITH METAL GATE AND FABRICATING METHOD OF THE SAME

(71) Applicant: UNITED MICROELECTRONICS CORP., Hsin-Chu City (TW)

(72) Inventors: Ping-Chen Tsai, Tainan City (TW); Shih-Wei Su, Tainan City (TW); Chih-Wei Chang, Tainan City (TW); Bin-Siang Tsai, Changhua County (TW)

(73) Assignee: UNITED MICROELECTRONICS CORP., Hsin-Chu City (TW)

(21) Appl. No.: 19/173,831

(22) Filed: Apr. 9, 2025

(30) Foreign Application Priority Data
Mar. 25, 2025 (TW) 114111241

(51) Int. Cl. H10D 64/68; H10D 64/01; H10D 64/27

(52) U.S. Cl. CPC H10D 64/685; H10D 64/01; H10D 64/516; H10D 64/693

(57) ABSTRACT

A transistor structure with a metal gate includes a semiconductor substrate. A dielectric layer covers the semiconductor substrate, and a recess is formed in the dielectric layer. A metal gate is disposed in the recess, and a U-shaped composite layer is disposed at two sides and a bottom of the metal gate. A cap layer is placed in the recess and disposed on the metal gate and U-shaped composite layer. The cap layer includes a first silicon nitride layer, a second silicon nitride layer, a silicon oxynitride layer, and a silicon oxide block. The silicon oxide block is disposed at the center of the cap layer. The nitrogen-to-silicon atomic ratio in the second silicon nitride layer is between 0.6 and 1.2.

### BACKGROUND OF THE INVENTION

### 1. Field of the Invention

The present invention relates to a transistor structure with a metal gate and a fabricating method of the same, particularly to a transistor structure with a cap layer made of two different types of silicon nitride layers and a fabricating method of the transistor.

### 2. Description of the Prior Art

A transistor is a core component in modern electronic technology, widely used in fields such as computers, communications, and medical equipment. It primarily functions as a switch to control the on/off state of electronic signals, enabling logical operations in digital circuits, and supporting the operation of modern processors and digital devices. Additionally, transistors can act as amplifiers, used to amplify weak electrical signals, and are widely applied in audio and wireless communication systems.

With the miniaturization of manufacturing technologies, the size of transistors continues to shrink, bringing higher computational performance and energy efficiency. However, this also presents a series of challenges during manufacturing. For instance, as the size decreases, gate leakage currents and short-channel effects increase, affecting the performance and stability of the transistor. Furthermore, issues such as material defects and incomplete metallization may arise during the miniaturization process, negatively impacting the component's performance.

Despite these challenges, transistors remain the cornerstone of modern electronic technology and play an irreplaceable role in various industries. The future challenge is how to overcome manufacturing defects in order to achieve more efficient and stable transistor designs and manufacturing processes.

### SUMMARY OF THE INVENTION

In view of this, the present invention provides a method for fabricating a cap layer of a metal gate, which can prevent defects or voids from forming within the cap layer.

According to a preferred embodiment of the present invention, a transistor structure with a metal gate includes a semiconductor substrate. A dielectric layer covers the semiconductor substrate. A recess is disposed in the dielectric layer. A metal gate is disposed in the recess. A U-shaped composite layer is disposed at two sides and a bottom of the metal gate, wherein a top surface of the metal gate protrudes from two ends of the U-shaped composite layer. A cap layer is disposed in the recess and on the metal gate and U-shaped composite layer, wherein the cap layer includes a first silicon nitride layer, a second silicon nitride layer, a silicon oxynitride layer, and a silicon oxide block. The silicon oxide block is disposed at a center of the cap layer. The silicon oxynitride layer, the second silicon nitride layer, and the first silicon nitride layer surround the silicon oxide block sequentially in a listed order from closer to the silicon oxide block to farther from the silicon oxide block; wherein a nitrogen-to-silicon atomic ratio in the second silicon nitride layer is between 0.6 and 1.2.

According to another preferred embodiment of the present invention, a fabricating method of a transistor structure with a metal gate includes providing a semiconductor substrate, wherein a dielectric layer covers the semiconductor substrate, a recess is disposed in the dielectric layer, a metal gate is disposed in the recess, a U-shaped composite layer is positioned at two sides and a bottom of the metal gate, a top surface of the metal gate protrudes from two ends of the U-shaped composite layer. Next, a cap layer is formed in the recess, on the metal gate and on the U-shaped composite layer. A method of forming the cap layer includes performing a first deposition process to form a first silicon nitride layer covering and contacting the metal gate and the U-shaped composite layer, wherein the first deposition process includes using a first operating power and introducing a first silicon-containing gas. Later, a second deposition process is performing to form a second silicon nitride layer covering and contacting the first silicon nitride layer, wherein the second deposition process includes using 0.3 to 0.7 times of the first operating power and introducing 0.3 to 0.7 times of the first silicon-containing gas. Thereafter, a silicon oxide block is formed to cover and contact the second silicon nitride layer. After forming the silicon oxide block, a silicon oxynitride layer is formed to be disposed between the silicon oxide block and the second silicon nitride layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a transistor structure with a metal gate and a fabricating method according to a preferred embodiment of the present invention, wherein:

FIG. 1 depicts a metal gate with a U-shaped composite layer;

FIG. 2 is a fabricating stage in continuous of FIG. 1;

FIG. 3 is a fabricating stage in continuous of FIG. 2;

FIG. 4 is a fabricating stage in continuous of FIG. 3;

FIG. 5 is a fabricating stage in continuous of FIG. 4; and

FIG. 6 is a fabricating stage in continuous of FIG. 5;

### DETAILED DESCRIPTION

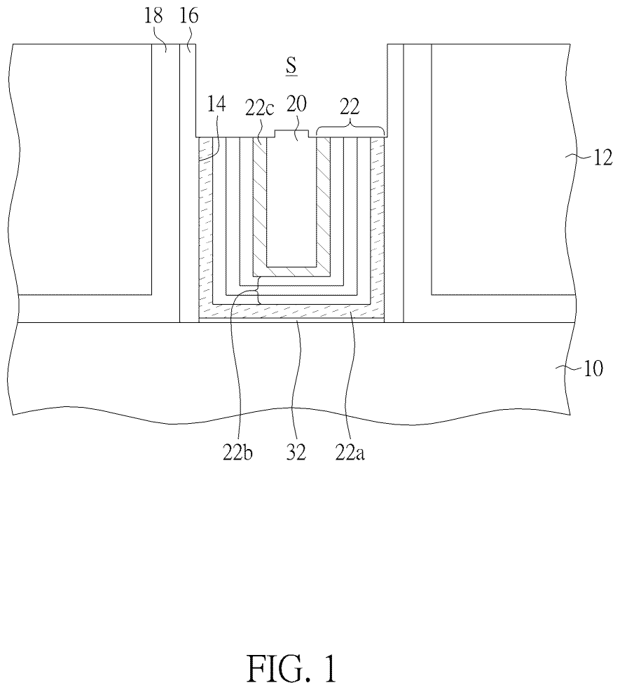

FIG. 1 to FIG. 6 depict a transistor structure with a metal gate and a fabricating method according to a preferred embodiment of the present invention.

As shown in FIG. 1, a semiconductor substrate 10 is provided. The semiconductor substrate 10 includes a germanium substrate, a gallium arsenide substrate, a silicon germanium substrate, an indium phosphide substrate, a gallium nitride substrate, a silicon carbide substrate, or a silicon-on-insulator substrate. The semiconductor substrate 10 can be a planar substrate or a fin structure. A dielectric layer 12 covers the semiconductor substrate 10, and a recess 14 is disposed in the dielectric layer 12. Liners 16 and spacers 18 are preferably respectively disposed at two sides of the recess 14. A metal gate 20 is disposed in the recess 14. A U-shaped composite layer 22 is disposed on two sides and the bottom of the metal gate 20. The top surface of the metal gate 20 protrudes from two ends of the U-shaped composite layer 22. The metal gate 20 and the U-shaped composite layer 22 are disposed in the lower half of the recess 14. At this stage, the upper half of the recess 14 is a space S. The space S is for accommodating a cap layer which will be formed in subsequent processes.

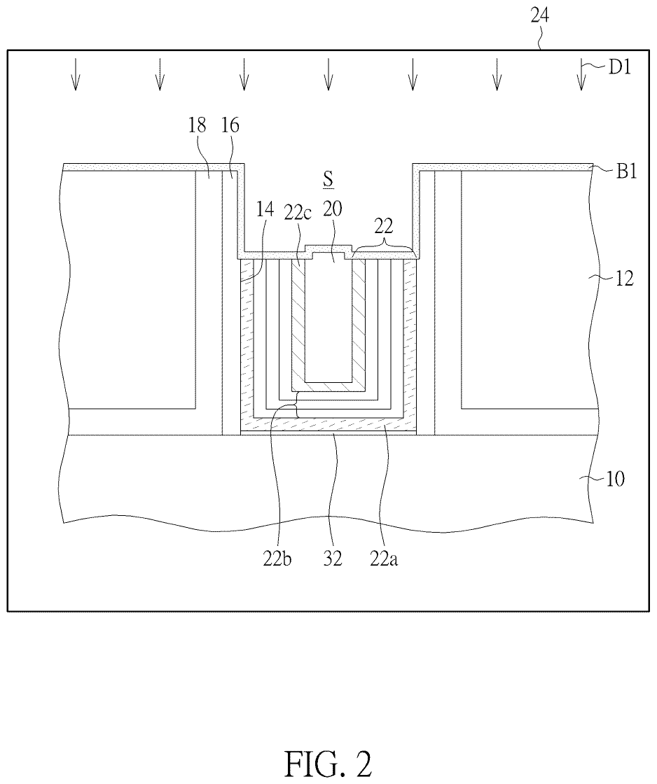

As shown in FIG. 2, a first deposition process D1 is carried out to form a first silicon nitride layer B1 to conformally cover and contact the metal gate 20, the U-shaped composite layer 22, and the top surface of the dielectric layer 12 outside of the recess 14. The first deposition process D1 is performed in a reaction chamber 24. The first deposition process D1 includes a chemical vapor deposition process, a physical vapor deposition process, or an atomic layer deposition process. The first deposition process D1 includes using a first operating power, introducing a first silicon-containing gas, and a first nitrogen-containing gas. The first silicon-containing gas and the first nitrogen-containing gas serve as precursors. According to the preferred embodiment of the present invention, the first deposition process D1 is performed by using a radio frequency (RF) source, with a preferred frequency of 13.56 MHz, but not limited thereto. The RF source has a first operating power ranging from 160 to 350 watts. The flow rate of the first silicon-containing gas is between 50 and 150 standard cubic centimeters per minute (sccm). The flow rate of the first nitrogen-containing gas is between 1000 and 10000 sccm. The operating temperature of the first deposition process D1 is preferably between 300° C. and 400° C. The first silicon-containing gas preferably includes silane (SiH₄), dimethylsilane (Si(CH₃)₂H₂, DMOS), silicon tetrafluoride (SiF₄), or silicon tetrachloride (SiCl₄), but is not limited thereto. The first nitrogen-containing gas preferably includes nitrogen gas, but is not limited thereto.

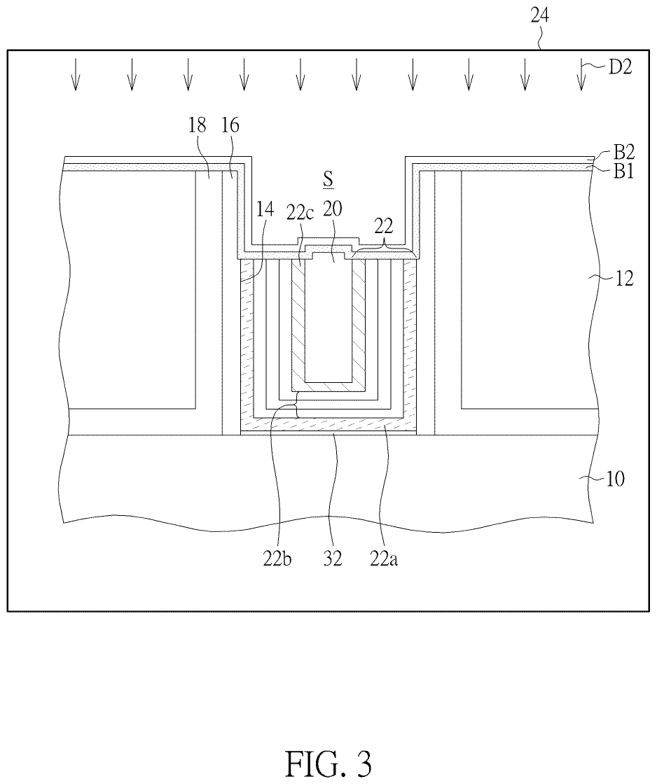

As shown in FIG. 3, a second deposition process D2 is performed in the reaction chamber 24 to form a second silicon nitride layer B2 to conformally cover and contact the first silicon nitride layer B1 and the top surface of the dielectric layer 12 outside of the recess 14. The second deposition process D2 includes reducing the first operating power and the first silicon-containing gas used in the first deposition process D1. Furthermore, the flow rate of the second nitrogen-containing gas can optionally be adjusted to 0.5 to 1.5 times of the flow rate of the first nitrogen-containing gas. Other parameters can be unchanged. In details, when switching from the first deposition process D1 to the second deposition process D2, the deposition equipment is not turned off. Instead, parameters are adjusted to slow down the rate of deposition to alter the properties of the silicon nitride being deposited. The second deposition process D2 includes using a second operating power, introducing a second silicon-containing gas, and a second nitrogen-containing gas. The second operating power is 0.3 to 0.7 times of the first operating power, and the second silicon-containing gas is 0.3 to 0.7 times of the first silicon-containing gas. According to a preferred embodiment of the present invention, the second operating power is preferably between 60 and 210 watts. The flow rate of the second silicon-containing gas is between 20 and 80 sccm, and the flow rate of the second nitrogen-containing gas is between 500 and 15,000 sccm. Since the deposition rate of the second deposition process D2 is slower, the second silicon nitride layer B2 will not form a hangover at the corners of the sidewalls of the recess 14 when covering the sidewalls of the recess 14. In addition, the silicon content of the second silicon nitride layer B2 is greater than the silicon content of the first silicon nitride layer B1. The second silicon-containing gas and the first silicon-containing gas are the same gas, and the second nitrogen-containing gas and the first nitrogen-containing gas are the same gas.

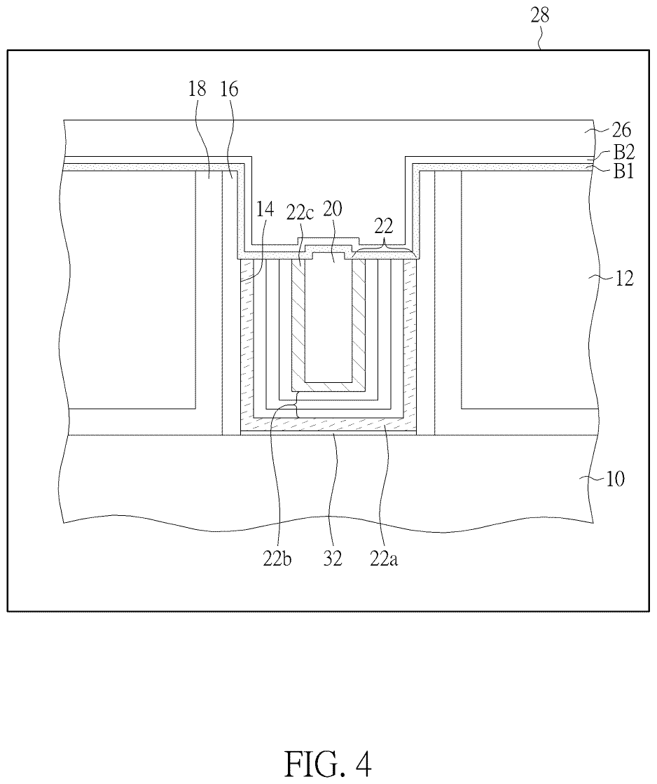

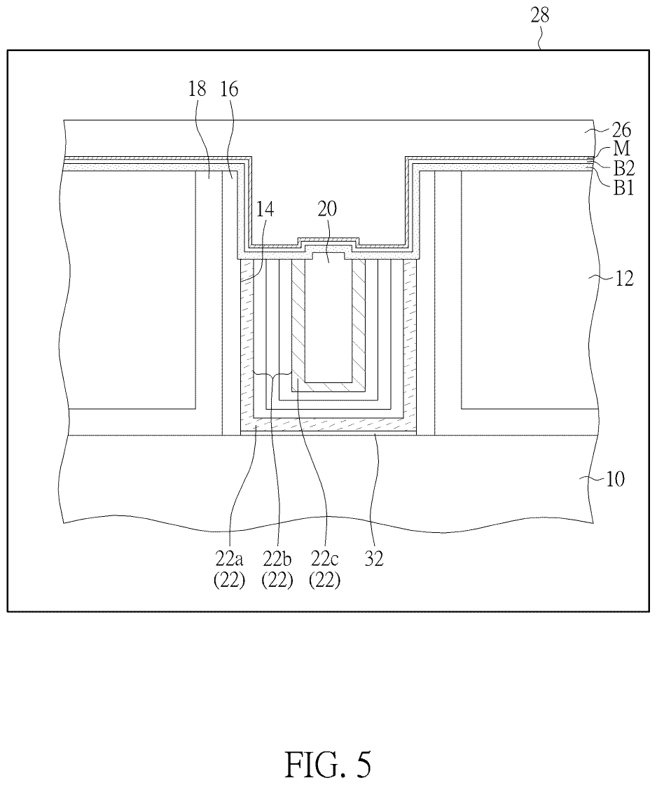

As shown in FIG. 4, a silicon oxide layer 26 is formed to fill the recess 14 and cover the second silicon nitride layer B2 outside of the recess 14. The formation of the silicon oxide layer 26 includes introducing ozone and silane into another reaction chamber 28 to deposit the silicon oxide layer. The silicon oxide layer 26 is then heated. Additionally, the silicon oxide layer 26 is not conformal with the recess 14. As shown in FIG. 5, when the silicon oxide layer 26 contacts the second silicon nitride layer B2, the surface of the second silicon nitride layer B2 will be oxidized by the silicon oxide layer 26 to form a silicon oxynitride layer M. In other words, the silicon oxynitride layer M is not formed by using a separate process. Instead, after the formation of the silicon oxide layer 26, because the silicon oxide layer 26 contacts the second silicon nitride layer B2, causing the surface of the second silicon nitride layer B2 to oxidize and form the silicon oxynitride layer M.

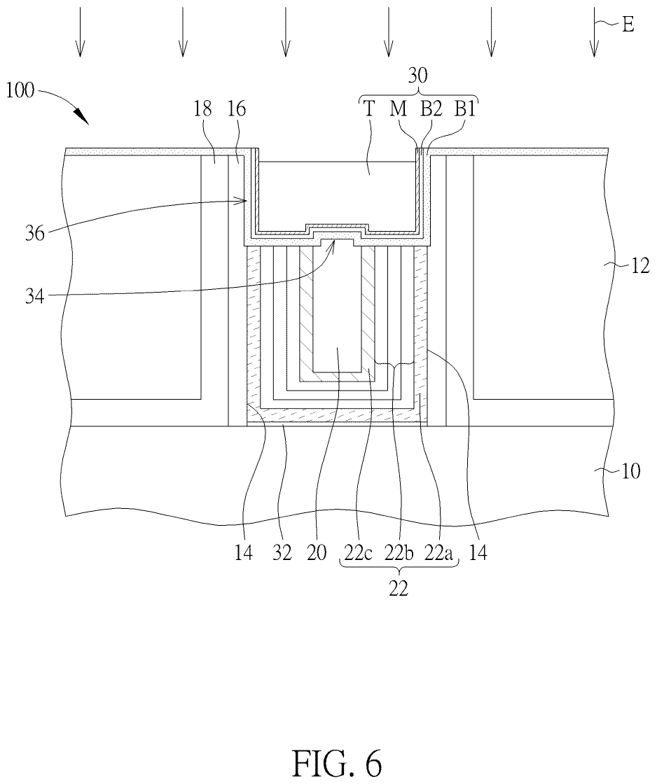

As shown in FIG. 6, a removal process E is performed by using the first silicon nitride layer B1 as an etch stop layer to remove the silicon oxide layer 26, the silicon oxynitride layer M, and the second silicon nitride layer B2 outside of the recess 14. The silicon oxide layer 26 remaining in the recess 14 becomes a silicon oxide block T. Since the first silicon nitride layer B1 serves as the etch stop layer, when the removal process E is completed, the first silicon nitride layer B1 will still cover the top surface of the dielectric layer 12 outside of the recess 14. At this point, the first silicon nitride layer B1, the second silicon nitride layer B2, the silicon oxynitride layer M, and the silicon oxide block T together form a cap layer 30. The top surface of the silicon oxide block T may be lower than the top surface of the first silicon nitride layer B1 on the dielectric layer 12. In another preferred embodiment, the top surface of the silicon oxide block T may be aligned with the top surface of the first silicon nitride layer B1 on the dielectric layer 12 outside of the recess 14. The removal process E is preferably a dry etching process. However, depending on different requirements, the removal process E can also be replaced with a chemical mechanical polishing (CMP) process. Thus, a metal gate transistor structure 100 according to the present invention is completed. Depending on different requirements, the metal gate transistor structure 100 can be applied to either N-type transistors or P-type transistors.

As shown in FIG. 6, a metal gate transistor structure 100 includes a semiconductor substrate 10. A dielectric layer 12 covers the semiconductor substrate 10, and a recess 14 is formed in the dielectric layer 12. A metal gate 20 is disposed in the recess 14. Liners 16 and spacers 18 are both disposed at two sides of the recess 14. A U-shaped composite layer 22 is located on two sides and the bottom of the metal gate 20. A gate dielectric layer 32 is disposed between the U-shaped composite layer 22 and the semiconductor substrate 10. The top surface of the metal gate 20 protrudes from two ends of the U-shaped composite layer 22. A cap layer 30 is disposed in the recess 14 and positioned on top of the metal gate 20 and the U-shaped composite layer 22. The cap layer 30 includes a first silicon nitride layer B1, a second silicon nitride layer B2, a silicon oxynitride layer M, and a silicon oxide block T. The silicon oxide block T is located at a center of the cap layer 30. The silicon oxynitride layer M, the second silicon nitride layer B2, and the first silicon nitride layer B1 surround the silicon oxide block T sequentially in a listed order from closer to the silicon oxide block T to farther from the silicon oxide block T. The bottom of the cap layer 30 includes a recessed opening 34, and the top surface of the metal gate 20 is embedded in the recessed opening 34. Additionally, the first silicon nitride layer B1, the second silicon nitride layer B2, and the silicon oxynitride layer M together form a trench profile 36. Moreover, the bottom of the trench profile 36 includes the recessed opening 34, and the bottom of the silicon oxide block T also includes the recessed opening 34.

The metal gate 20 includes one or more layers of metal materials, such as aluminum, tungsten, titanium, and the like. The gate dielectric layer 32 includes one or more layers of insulating material, such as silicon oxide, silicon oxynitride, silicon nitride, and the like. The U-shaped composite layer 22 includes a high dielectric constant layer 22a, at least one work function layer 22b, and a barrier layer 22c arranged sequentially from farther from the metal gate 20 to closer to the metal gate 20. The materials of the spacer 18 and the dielectric layer 12 respectively include silicon nitride, silicon oxide, or silicon oxynitride. The liner 16 includes silicon oxide. The high dielectric constant layer 22a includes aluminum oxide, zirconium oxide, barium strontium titanate (BST), lead zirconate titanate (PZT), zirconium silicate (ZrSiO₄), hafnium silicate (HfSiO₂), hafnium silicate oxide nitride (HfSiON), tantalum oxide, or a combination of the above materials. The work function layer 22b includes metals for the work function requirements of N-type transistors or metals for the work function requirements of P-type transistors. For example, the work function layer 22b includes titanium aluminum, zirconium aluminum, tungsten aluminum, tantalum aluminum, hafnium aluminum, titanium nitride, titanium carbide, tantalum nitride, tantalum carbide, tungsten carbide, titanium aluminum nitride. The barrier layer includes titanium, tantalum, titanium nitride, tantalum nitride, or their combinations. In this embodiment, the work function layer 22b is exemplified with three material layers, but it is not limited to this configuration.

Table 1 respectively shows atomic ratios, thicknesses, refractive indices, and etching rates of the first silicon nitride layer B1, the second silicon nitride layer B2, the silicon oxynitride layer M, and the silicon oxide block T.

TABLE 1

| | First Silicon | Second Silicon | Silicon | Silicon |
|---|---|---|---|---|
| | Nitride Layer | Nitride Layer | Oxynitride | Oxide |
| | B1 | B2 | Layer M | Block T |
| Atomic Ratio | 1.2~1.4 | 0.6~1.2 | 0.6~0.8 | <0.05 |
| (N/Si) | | | | |
| Atomic Ratio | <0.05 | <0.05 | 0.5~0.7 | 1-2 |
| (O/Si) | | | | |
| Thickness (Å) | 30~60 | 20~80 | 10~30 | — |
| Refractive | 1.85~2.25 | 2.20~2.60 | 1.60~1.90 | 1.40~1.50 |
| Index | | | | |
| Etching Rate | 20~30 | 9~18 | 70~230 | 70~230 |
| (Å/min) | | | | |

The nitrogen to silicon atomic ratios and the oxygen to silicon atomic ratios of the first silicon nitride layer B1, the second silicon nitride layer B2, the silicon oxynitride layer M, and the silicon oxide block T of the present invention are measured by using secondary ion mass spectroscopy (SIMS). The refractive indices are measured by using a light source with a wavelength of 633 nm. The etching rate is tested by using a diluted hydrofluoric acid etchant made with a volume ratio of hydrogen fluoride to water of 1:100. This diluted hydrofluoric acid is used to measure the etching rate of the first silicon nitride layer B1, the second silicon nitride layer B2, the silicon oxynitride layer M, and the silicon oxide block T.

Compared to the first silicon nitride layer B1, the invention reduces the formation rate of the second silicon nitride layer B2. As a result, the nitrogen-to-silicon atomic ratio in the second silicon nitride layer B2 is lower than that in the first silicon nitride layer B1. In other words, the silicon content in the second silicon nitride layer B2 is higher than that in the first silicon nitride layer B1. According to the preferred embodiment of the present invention, the nitrogen-to-silicon atomic ratio in the first silicon nitride layer B1 is between 1.2 and 1.4. The nitrogen-to-silicon atomic ratio in the second silicon nitride layer B2 is between 0.6 and 1.2. The atomic ratio in the present invention refers to the numerical ratio between the two types of atoms. As shown in Table 1, due to the different silicon contents, the etching rate of diluted hydrofluoric acid to the second silicon nitride layer B2 is lower than the etching rate of diluted hydrofluoric acid to the first silicon nitride layer B1. In other words, the second silicon nitride layer B2 has better etching resistance. Thus, during other etching processes, the second silicon nitride layer B2 can serve as a protective layer, preventing the etching solution from penetrating downward from the cap layer 30. Therefore, the metal gate 20 and the U-shaped composite layer 22 can be protected from damage caused by the etching solution.

Furthermore, because the second silicon nitride layer B2 uses different processing conditions from that of the first silicon nitride layer B1, the second silicon nitride layer B2 has neutral stress, while the first silicon nitride layer B1 has compressive stress, although the second silicon nitride layer B2 and the first silicon nitride layer B1 are both silicon nitride. The stress of the second silicon nitride layer B2 is between-50 MPa and 50 MPa. According to general definitions, a stress range of −50 MPa to 50 MPa can be considered neutral stress. In addition, the silicon oxide block T has tensile stress. Since the second silicon nitride layer B2 has neutral stress, the thicker the second silicon nitride layer B2, the more the second silicon nitride layer B can make the overall stress of the cap layer 30 approach neutrality. As the stress of the cap layer 30 tends to be neutral, the impact of the stress from the cap layer 30 to the gate channel below becomes smaller. In this embodiment, the summation of the stresses of the first silicon nitride layer B1, the second silicon nitride layer B2, the silicon oxynitride layer M, and the silicon oxide block T is preferably neutral stress. In other words, the cap layer 30 is preferably neutral stress. In addition, since the silicon oxynitride layer M is formed by oxidizing the surface of the second silicon nitride layer B2, the thickness of the second silicon nitride layer B2 will be greater than the thickness of the silicon oxynitride layer M.

As shown in Table 1, the physical and chemical properties of the first silicon nitride layer B1 and the second silicon nitride layer B2 are different. Therefore, the first silicon nitride layer B1 and the second silicon nitride layer B2 are two types of silicon nitride with different characteristics. In the present invention, the first deposition process D1 and the second deposition process D2 are performed in the same reaction chamber 24. By reducing the precursor flow and operating power, the second silicon nitride layer B2 can be prevented from forming hangovers on the sidewalls of the recess 14, whereas in conventional processes, the formation of hangovers leads to voids in the cap layer. Additionally, the second silicon nitride layer B2 has better etching resistance and neutral stress, which helps protect the metal gate 20 and the U-shaped composite layer 22 below. The second silicon nitride layer B2 also ensures that the overall stress of the cap layer 30 remains neutral, thereby reducing the impact of stress on the gate channel.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transistor structure with a metal gate, comprising:
a semiconductor substrate;
a dielectric layer covering the semiconductor substrate;
a recess disposed in the dielectric layer;
a metal gate disposed in the recess;
a U-shaped composite layer disposed at two sides and a bottom of the metal gate, wherein a top surface of the metal gate protrudes from two ends of the U-shaped composite layer; and
a cap layer disposed in the recess and on the metal gate and U-shaped composite layer, wherein the cap layer comprises a first silicon nitride layer, a second silicon nitride layer, a silicon oxynitride layer, and a silicon oxide block, the silicon oxide block is disposed at a center of the cap layer, and the silicon oxynitride layer, the second silicon nitride layer, and the first silicon nitride layer surround the silicon oxide block sequentially in a listed order from closer to the silicon oxide block to farther from the silicon oxide block; wherein a nitrogen-to-silicon atomic ratio in the second silicon nitride layer is between 0.6 and 1.2.

2. The transistor structure with a metal gate of claim 1, wherein a nitrogen-to-silicon atomic ratio in the first silicon nitride layer is between 1.2 and 1.4.

3. The transistor structure with a metal gate of claim 1, wherein a nitrogen-to-silicon atomic ratio in the first silicon nitride layer is greater than the nitrogen-to-silicon atomic ratio in the second silicon nitride layer.

4. The transistor structure with a metal gate of claim 3, wherein the nitrogen-to-silicon atomic ratio in the second silicon nitride layer is greater than a nitrogen-to-silicon atomic ratio in the silicon oxynitride layer.

5. The transistor structure with a metal gate of claim 1, wherein the first silicon nitride layer has a compressive stress, the second silicon nitride layer has a neutral stress, and the silicon oxide block has a tensile stress.

6. The transistor structure with a metal gate of claim 1, wherein a thickness of the second silicon nitride layer is greater than a thickness of the silicon oxynitride layer.

7. The transistor structure with a metal gate of claim 1, a bottom of the cap layer includes a recessed opening, and the top surface of the metal gate is embedded in the recessed opening.

8. The transistor structure with a metal gate of claim 7, wherein the first silicon nitride layer, the second silicon nitride layer, and the silicon oxynitride layer together form a trench profile, and a bottom of the trench profile comprises the recessed opening.

9. The transistor structure with a metal gate of claim 1, wherein the U-shaped composite layer comprises a high dielectric material layer, at least one work function layer, and at least a barrier layer.

10. The transistor structure with a metal gate of claim 1, wherein when using diluted hydrofluoric acid as an etchant, an etch rate of the diluted hydrofluoric acid for the second silicon nitride layer is lower than an etch rate of the diluted hydrofluoric acid for the first silicon nitride layer.

11. A fabricating method of a transistor structure with a metal gate, comprising:
providing a semiconductor substrate, wherein a dielectric layer covers the semiconductor substrate, a recess is disposed in the dielectric layer, a metal gate is disposed in the recess, a U-shaped composite layer is positioned at two sides and a bottom of the metal gate, a top surface of the metal gate protrudes from two ends of the U-shaped composite layer;
forming a cap layer in the recess, on the metal gate and on the U-shaped composite layer, wherein a method of forming the cap layer comprises:
performing a first deposition process to form a first silicon nitride layer covering and contacting the metal gate and the U-shaped composite layer, wherein the first deposition process comprises using a first operating power and introducing a first silicon-containing gas;
performing a second deposition process to form a second silicon nitride layer covering and contacting the first silicon nitride layer, wherein the second deposition process comprises using 0.3 to 0.7 times of the first operating power and introducing 0.3 to 0.7 times of the first silicon-containing gas;
forming a silicon oxide block to cover and contact the second silicon nitride layer; and
after forming the silicon oxide block, forming a silicon oxynitride layer disposed between the silicon oxide block and the second silicon nitride layer.

12. The fabricating method of a transistor structure with a metal gate of claim 11, wherein the silicon oxynitride layer is formed by directly contacting the silicon oxide block with the second silicon nitride layer.

13. The fabricating method of a transistor structure with a metal gate of claim 11, wherein the first operating power is between 160 and 350 watts, and a flow rate of the first silicon-containing gas is between 50 and 150 standard cubic centimeters per minute (sccm).

14. The fabricating method of a transistor structure with a metal gate of claim 11, wherein steps of forming the cap layer further comprise:
when forming the first silicon nitride layer, the first silicon nitride layer covering and contacting a top surface of the dielectric layer outside the recess;
when forming the second silicon nitride layer, the second silicon nitride layer covering the top surface of the dielectric layer outside the recess;
forming a silicon oxide layer to fill the recess and cover the second silicon nitride layer outside the recess;
forming the silicon oxynitride layer; and
performing a removal process by using the first silicon nitride layer as an etch stop layer to remove the silicon oxide layer, the silicon oxynitride layer, and the second silicon nitride layer outside of the recess, wherein the silicon oxide layer remaining in the recess becomes the silicon oxide block.

15. The fabricating method of a transistor structure with a metal gate of claim 14, wherein the removal process is a dry etching process or a chemical mechanical polishing process.

16. The fabricating method of a transistor structure with a metal gate of claim 11, wherein a nitrogen-to-silicon atomic ratio in the second silicon nitride layer is between 0.6 and 1.2.

17. The fabricating method of a transistor structure with a metal gate of claim 11, wherein a nitrogen-to-silicon atomic ratio in the first silicon nitride layer is between 1.2 and 1.4.

18. The fabricating method of a transistor structure with a metal gate of claim 11, wherein the first silicon nitride layer has a compressive stress, the second silicon nitride layer has a neutral stress, and the silicon oxide block has a tensile stress.

19. The fabricating method of a transistor structure with a metal gate of claim 11, wherein when using diluted hydrofluoric acid as an etchant, an etch rate of the diluted hydrofluoric acid for the second silicon nitride layer is lower than an etch rate of the diluted hydrofluoric acid for the first silicon nitride layer.
